(19) United States
(12) Patent Application Publication
(10) Pub. No.: US 2002/0045348 A1
(43) Pub. Date: Apr. 18, 2002

(54) Semiconductor wafer treating method and device for removing deposit on a semiconductor wafer

(76) Inventor: Kazuhisa Arai, Tokyo (JP)

Correspondence Address: SMITH, GAMBRELL & RUSSELL, LLP, 1850 M Street, N.W., Suite 800, Washington, DC, 20036, US

(21) Appl. No.: 09/893,781

(22) Filed: Jun. 29, 2001

(30) Foreign Application Priority Data
Jul. 7, 2000 (JP) 2000-207365

(51) Int. Cl. H01L 21/302; H01L 21/461

(52) U.S. Cl. 438/690; 438/906

(57) ABSTRACT

A semiconductor wafer treating method comprising treating steps for forming a circuit on the front surface of a semiconductor, comprising the step of removing a deposit formed in the treating steps and adhered to the periphery and the rear surface of the semiconductor wafer, the deposit removing step being carried out between any optional steps in the treating steps.

### FIELD OF THE INVENTION

The present invention relates to a semiconductor wafer treating method for forming a circuit on the front surface of a semiconductor wafer, and a device for removing a deposit on a semiconductor wafer.

### DESCRIPTION OF THE PRIOR ART

A circuit such as LSI is formed on the front surface of a semiconductor wafer by laminating complicated and fine circuits through a number of steps such as a diffusion step, thin film forming step, exposure step, wafer surface state inspecting step, cleaning step and the like. For example, in the step of forming a highly dielectric film such as a SiO₂ film, Si₃N₄ film, Ta₂O₅ film, BaxSri.xTiO₃ film, a treatment with a high-purity gas is required to be made. If impurities such as a copper atom and aluminum atom are contained in the treating gas, they cause to reduce quality of a circuit such as LSI. Therefore, it is necessary to sufficiently eliminate impurities from the treating gas.

Under the circumstances, the inventor of the present invention has studied the cause of containing impurities to cope with this and has found an unexpected fact. That is the following mechanism. When a copper wire or aluminum wire is formed on the circuit in the step of forming a thin film by CVD or the like in the course of forming the circuit on the front surface of the semiconductor wafer, metals such as copper or aluminum accumulates on the periphery and the rear surface of the semiconductor wafer. Meanwhile, the semiconductor wafer is carried by the carrying means between steps, and at this occasion of the semiconductor wafer being carried, metal atoms deposited on the periphery and the rear surface of the semiconductor wafer are adhered to a carrying means. When a semiconductor wafer of a different type is carried by the carrying means to which the metal atoms are thus adhered, the metal atoms adhered to the carrying means are adhered to the above semiconductor wafer of a different type. Thus, impurities such as metal atoms are contained in the treating gas.

Particularly in an inspection device for inspecting the surface state of the semiconductor wafer, as different types of semiconductor wafers are taken in to be inspected, metals deposited on the periphery and the rear surface of each semiconductor wafer are adhered to the carrying means and the table of the inspection device, and causes cross contamination.

### SUMMARY OF THE INVENTION

It is an object of the present invention to provide a semiconductor wafer treating method and a device for removing a deposit on a semiconductor wafer, both of which can eliminate impurities from a treatment gas by preventing the occurrence of cross contamination in treating steps for forming a circuit on the front surface of the semiconductor wafer.

To attain the above object, according to the present invention, there is provided a semiconductor wafer treating method comprising treating steps for forming a circuit on the front surface of a semiconductor wafer, wherein

the method further comprises the step of removing a deposit formed in the treating steps and adhered to the periphery and the rear surface of the semiconductor wafer, the deposit removing step being carried out between any optional steps in the treating steps.

The above deposit removing step includes the sub-step of placing the semiconductor wafer on a chuck table and suction-holding it on the chuck table and the sub-step of polishing the periphery and the rear surface of the semiconductor wafer suction-held on the chuck table. The polishing sub-step is desirably carried out with throwaway abrasive tapes.

According to the present invention, there is provided a device for removing a deposit adhered to the periphery and the rear surface of a semiconductor wafer, comprising a chuck table for suction-holding the semiconductor wafer, the chuck table being rotary driven, a first grinding means arranged above the chuck table and a second grinding means arranged in a sideward direction of the chuck table, wherein

the first grinding means comprises an abrasive tape, an abrasive tape roll wound with the abrasive tape, a take-up roll for taking up the abrasive tape wound round the abrasive tape roll, and a pressing roll, interposed between the abrasive tape roll and the take-up roll, for pressing the abrasive tape against the rear surface of the semiconductor wafer whose front surface is placed on the chuck table; and

the second grinding means comprises an abrasive tape, an abrasive tape roll wound with the abrasive tape and arranged below or above the top surface of the chuck table, a take-up roll for taking up the abrasive tape wound round the abrasive tape roll arranged above or below the top surface of the chuck table, and two pressing rolls, interposed between the abrasive tape roll and the take-up roll, for pressing the abrasive tape between the two pressing rolls against the periphery of the semiconductor wafer placed on the chuck table.

### BRIEF DESCRIPTION OF THE DRAWINGS

FIG. 1 is a schematic structural diagram of a device for removing a deposit for carrying out the semiconductor wafer treating method of the present invention; and

FIG. 2 is a sectional view cut along line A-A of FIG. 1.

### DETAILED DESCRIPTION OF THE PREFERRED EMBODIMENTS

Preferred embodiments of the semiconductor wafer treating method and the device for removing a deposit on a semiconductor wafer of the present invention will be described in detail with reference to the accompanying drawings.

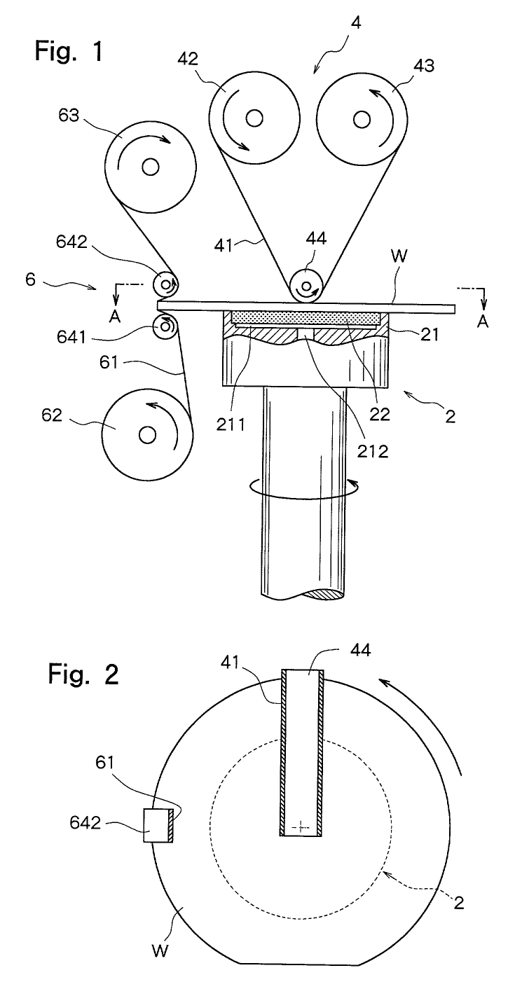

FIG. 1 is a schematic structural diagram of the device for removing a deposit for carrying out a deposit removing step.

The device for removing a deposit on a semiconductor wafer in the illustrated embodiment comprises a chuck table 2 for holding a semiconductor wafer. This chuck table 2 consists of a disk-like base 21 having a circular depression 211 whose top is open and a suction-holding chuck 22 which is formed of a porous ceramic board fitted in the depression 211 formed in the base 21 and is constructed to be turned in a direction indicated by an arrow by a rotary drive unit that is not shown. Communication holes 212 open to the depression 211 are formed in the base 21 and connected to a suction means that is not shown. The semiconductor wafer W is placed on the thus constituted chuck table 2 in such a manner that its front surface (i.e., a surface on which the circuit is formed) faces down. At this time, a protective tape is affixed to the front surface of the semiconductor wafer W to protect the formed circuit and prevent a metal such as copper or aluminum for forming a circuit from adhering to the chuck table 2. Therefore, in the semiconductor wafer W placed on the chuck table 2, its rear surface on which the metal such as copper or aluminum accumulates in the step of forming a circuit on the front surface faces up. The semiconductor wafer W thus placed on the chuck table 2 is suction-held on the chuck table 2 by activating a suction means (not shown).

The device for removing a deposit on a semiconductor wafer in the illustrated embodiment comprises a first grinding means 4 disposed above the chuck table 2. This first grinding means 4 comprises an abrasive tape 41, an abrasive tape roll 42 wound with the abrasive tape 41, a take-up roll 43 for taking up the abrasive tape 41 wounded round the abrasive tape roll 42, and a pressing roll 44, interposed between the abrasive tape roll 42 and the take-up roll 43, for pressing the abrasive tape 41 against the top surface (rear surface) of the semiconductor wafer W on the chuck table 2. The abrasive tape 41 of the thus constituted first grinding means 4 has a width set longer than the radius of the semiconductor wafer W as shown in FIG. 2 and is used to a range from the periphery to the center of the semiconductor wafer W.

The device for removing a deposit on the semiconductor wafer in the illustrated embodiment comprises a second grinding means 6 disposed in a sideward direction of the chuck table 2. This second grinding means 6 comprises an abrasive tape 61, an abrasive tape roll 62 wound with the abrasive tape 61 and arranged below the top of the chuck table 2, a take-up roll 63, arranged above the top of the chuck table 2, for taking up the abrasive tape 61 wound round the abrasive tape roll 62, and two pressing rolls 641 and 642, interposed between the abrasive tape roll 62 and the take-up roll 63, for pressing the abrasive tape 61 between the two pressing rolls 641 and 642 against the periphery of the semiconductor wafer W held on the chuck table 2. In the above-described second grinding means 6, the abrasive tape roll 62 is arranged below the top surface of the chuck table 2 and the take-up roll 63 is arranged above the top surface of the chuck table 2. The abrasive tape roll 62 may be arranged above the top surface of the chuck table 2 and the take-up roll 63 may be arranged below the top surface of the chuck table 2.

The device for removing a deposit on a semiconductor wafer in the illustrated embodiment is constituted as described above and its deposit removing operation will be described hereinafter.

The semiconductor wafer W is suction-held on the chuck table 2 in such a manner that the rear surface on which metals such as copper or aluminum accumulate faces up, and the rotary drive unit (not shown) is activated to turn the chuck table 2 in a direction indicated by an arrow in FIG. 1 and FIG. 2. The take-up rolls 43 and 63 of the first grinding means 4 and the second grinding means 6 are turned in directions indicated by arrows in FIG. 1 by activating rotary drive units (not shown), respectively. As a result, the metals such as copper or aluminum deposited on the rear surface and the periphery of the semiconductor wafer W is ground and removed by the abrasive tapes 41 and 61, respectively. Since the abrasive tapes 41 and 61 wound round the abrasive tape rolls 42 and 62 are throwaway abrasive tapes wound by the take-up rolls 43 and 63 in the first grinding means 4 and the second grinding means 6 in the illustrated embodiment, respectively, the metals adhered to the abrasive tapes are not adhered to a semiconductor wafer to be treated next. The above deposit removing step can be carried out between any treating steps for forming a circuit on the front surface of the semiconductor wafer.

Since the semiconductor wafer treating method and the device for removing a deposit on a semiconductor wafer of the present invention are constituted as described above, they have the following function and effect.

That is, according to the present invention, since the method comprises the step of removing a deposit formed in the treating steps and adhered to the periphery and the rear surface of the semiconductor wafer, which is carried out between any treatment steps for forming a circuit on the front surface of the semiconductor wafer, the cross contamination of metals which generate between different types of semiconductor wafers with the aid of a carrying means or the like can be prevented. Therefore, the purity of a highly dielectric film such as a SiO₂ film, Si₃N₄ film, Ta₂O₅ film, BaxSri.xTiO₃ film formed in the treating steps for forming a circuit on the front surface of the semiconductor wafer can be improved, thereby making it possible to form a high-quality circuit. The improved purity of a raw material for forming a circuit extends the service life of the circuit and stabilizes leak voltage and gate voltage, resulting in the improved reliability of the circuit.

In the present invention, the above deposit removing step comprises the sub-step of placing the semiconductor wafer on the chuck table and suction-holding it on the chuck table and the sub-step of polishing the periphery and the rear surface of the semiconductor wafer suction-held on the chuck table. Since the polishing sub-step is carried out with the throwaway abrasive tapes and the throwaway abrasive tapes are wound and scrapped, the occurrence of cross contamination through abrasive whetstones can be prevented with certainty.

What is claimed is:

1. A semiconductor wafer treating method comprising treating steps for forming a circuit on the front surface of a semiconductor wafer, wherein
the method further comprises the step of removing a deposit formed in the treating steps and adhered to the periphery and the rear surface of the semiconductor wafer, the deposit removing step being carried out between any optional steps in the treating steps.

2. The semiconductor wafer treating method of claim 1, wherein the deposit removing step includes the sub-step of placing the semiconductor wafer on a chuck table and suction-holding it on the chuck table and the sub-step of polishing the periphery and the rear surface of the semiconductor wafer suction-held on the chuck table.

3. The semiconductor wafer treating method of claim 2, wherein the polishing sub-step is carried out by throwaway abrasive tapes.

4. A device for removing a deposit adhered to the periphery and the rear surface of a semiconductor wafer, comprising a chuck table for suction-holding the semiconductor wafer, the chuck table being rotary driven, a first grinding means arranged above the chuck table and a second grinding means arranged in a sideward direction of the chuck table, wherein
the first grinding means comprises an abrasive tape, an abrasive tape roll wound with the abrasive tape, a take-up roll for taking up the abrasive tape wound round the abrasive tape roll, and a pressing roll, interposed between the abrasive tape roll and the take-up roll, for pressing the abrasive tape against the rear surface of the semiconductor wafer whose front surface is placed on the chuck table; and
the second grinding means comprises an abrasive tape, an abrasive tape roll wound with the abrasive tape and arranged below or above the top surface of the chuck table, a take-up roll for taking up the abrasive tape wound round the abrasive tape roll arranged above or below the top surface of the chuck table, and two pressing rolls, interposed between the abrasive tape roll and the take-up roll, for pressing the abrasive tape between the two pressing rolls against the periphery of the semiconductor wafer placed on the chuck table.
